(19) United States
(12) Patent Application Publication
(10) Pub. No.: US 2005/0057885 A1
(43) Pub. Date: Mar. 17, 2005

(54) Method of eliminating brownian noise in micromachined varactors

(76) Inventor: Marvin Glenn Wong, Woodland Park, CO (US)

Correspondence Address: AGILENT TECHNOLOGIES, INC.;Legal Department, DL429, Intellectual Property Administration, P. O. Box 7599, Loveland, CO, 80537-0599, US

(21) Appl. No.: 10/963,198

(22) Filed: Oct. 12, 2004

Related U.S. Application Data
(63) Continuation of application No. 10/004,035, filed on Oct. 31, 2001.

(51) Int. Cl. H03B 5/08

(52) U.S. Cl. 361/302

(57) ABSTRACT

In accordance with the invention, Brownian noise caused by molecular gas collisions in a micromachined varactor are substantially reduced, and even eliminated, by specialized packaging of the micromachined varactor. The packaging of the micromachined varactor provides for altering the environment of the micromachined varactor so that it is in a vacuum rather than in a gas. Accordingly, the random pressure fluctuations may be completely eliminated. Since a varactor is a device in which the moveable parts do not make contact with the fixed parts, and then separate, stiction is not a problem.

### BACKGROUND

Micromachined varactors are generally made with a capacitor structure consisting of one or more fixed capacitor plates and one or more moveable capacitor plates. The capacitance is adjusted by moving the movable plate or plates relative to the fixed plate or plates. Actuation can be by electrostatic, thermal or magnetic means, for example. Those skilled in the art will understand that multiple optional embodiments are possible.

The gas pressure on any two opposite sides of the movable plate structure are due to the collisions of gas molecules. Since the structures are small, these collisions may be unbalanced at any time. Unbalanced collisions causes the moveable plate to have small random movements. These small random movements are called Brownian motion. The Brownian motion also causes the capacitance to vary randomly. The random variance in capacitance is called Brownian noise. Brownian noise is undesirable for a well controlled varactor and causes performance degradations in the device.

### SUMMARY

The present invention is directed to a microelectromechanical system (MEMS) actuator assembly. Moreover, the present invention is directed to a method of eliminating Brownian noise in micromachined varactors.

In accordance with the invention, Brownian noise caused by molecular gas collisions in a micromachined varactor are substantially reduced, and even eliminated, by specialized packaging of the micromachined varactor. The packaging of the micromachined varactor provides for altering the environment of the micromachined varactor so that it is in a vacuum rather than in a gas. Accordingly, the random pressure fluctuations may be completely eliminated. Since a varactor is a device in which the moveable parts do not make contact with the fixed parts, and then separate, stiction is not a problem.

### DESCRIPTION OF THE DRAWINGS

The invention can be better understood with reference to the following drawings. The components in the drawings are not necessarily to scale, emphasis instead being placed upon clearly illustrating the principles of the present invention.

FIG. 1 shows a side view of a micromachined varactor.

FIG. 2 shows a side view of a varactor in accordance with the invention.

FIG. 3 shows a side view of an alternative embodiment of a varactor in accordance with the invention.

### DETAILED DESCRIPTION OF THE INVENTION

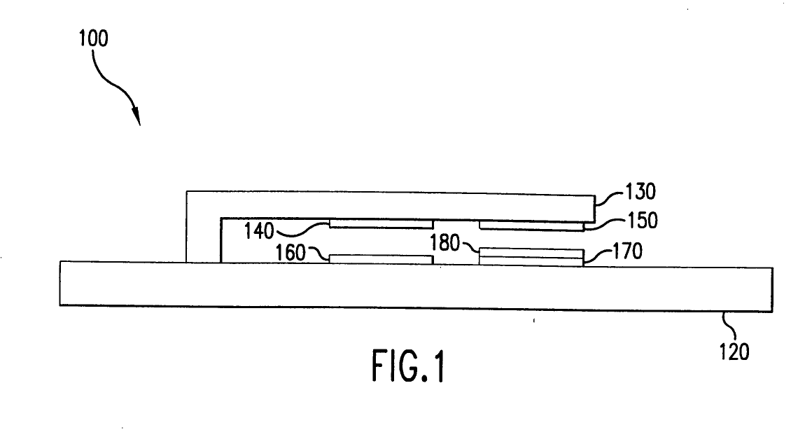

The varactor 100 shown, shown in FIG. 1, includes a substrate 120 which acts as support for the switching mechanism and provides a non-conductive dielectric platform. The varactor 100 shown in FIG. 1 also includes deflecting beam 130 connected to the substrate 110. In common fashion, the deflecting beam 130 forms an L shape with the short end of the deflecting beam 130 connecting to the substrate. The deflecting beam 130 is constructed from a non-conductive material. The deflecting beam 130 has an attracted plate 140 and a first signal path plate 150 connected to the long leg. An actuator plate 160 is connected to the substrate directly opposing the attracted plate. A second signal path plate 170 is connected to the substrate directly opposing the signal path plate 150.

The cantilever beam 130 shown in FIG. 1 is portrayed for purposes of example. It is understood by those skilled in the art that other types of deflecting beams are possible and commonly utilized in the art. One such deflecting beam is a beam fixed at both ends.

During operation of the varactor shown in FIG. 1, a charge is applied to actuator plate 160 causing attracted plate 140 to be electrically attracted thereto. This electrical attraction causes bending of the deflecting beam 130. Bending of the deflecting beam 130 causes the first signal path plate 50 and the second signal path plate 170 to near each other. The nearness of the first and second signal path plates 150, 170 causes capacitive coupling, thus allowing the varactor 100 to achieve the desired capacitance value. To adjust the varactor, the voltage difference between the actuator plate 160 and the attracted plate 140 is changed, the deflecting beam moves to a new equilibrium position with a new spacing between the actuator plate and attracted plate, and the resulting new spacing between the signal path plates produces a new, controlled capacitance value.

A dielectric pad 180 is commonly attached to one or both of the signal path plates 150, 170. A dielectric pad is not shown attached to signal path plate 150 in FIG. 1. The dielectric pad prohibits the signal path plates 150, 170 from coming in contact during the bending of the deflecting beam.

It is understood by those skilled in the art that the size of many varactors makes them susceptible to disturbances caused by collisions of gas particles. When collisions of gas particles are unbalanced in relation to the deflecting beam 130, such collisions can cause the beam 130 exhibit Brownian motion. The Brownian motion causes the distance between the signal plates to randomly vary. The random variation in the distance between the signal plates results in a variance in the resulting capacitance, thus resulting in Brownian noise in the signal path.

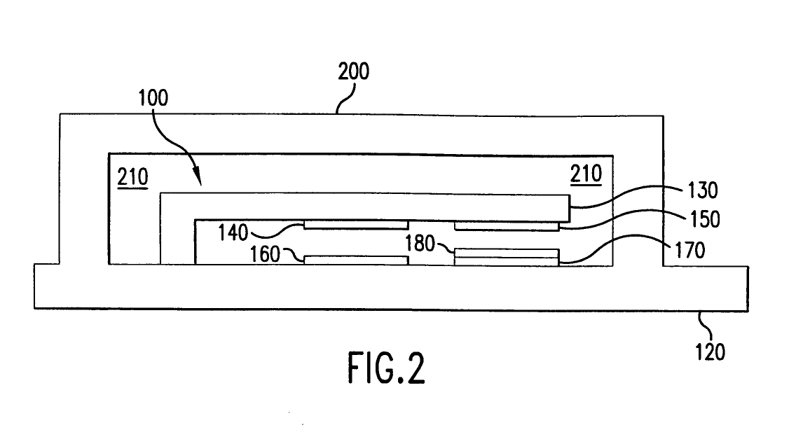

FIG. 2 shows the varactor of FIG. 1 and a packaging 200 surrounding the varactor 130 which is connected to the substrate 120. The packaging 200 surrounding the varactor 130 forms a chamber 210 which is airtight. During construction of the varactor 130 and the packaging 200, all gas molecules are removed from the chamber 210. The chamber 210 is sealed to preserve the vacuum. Removal of the gas molecules results in elimination of collisions of gas molecules.

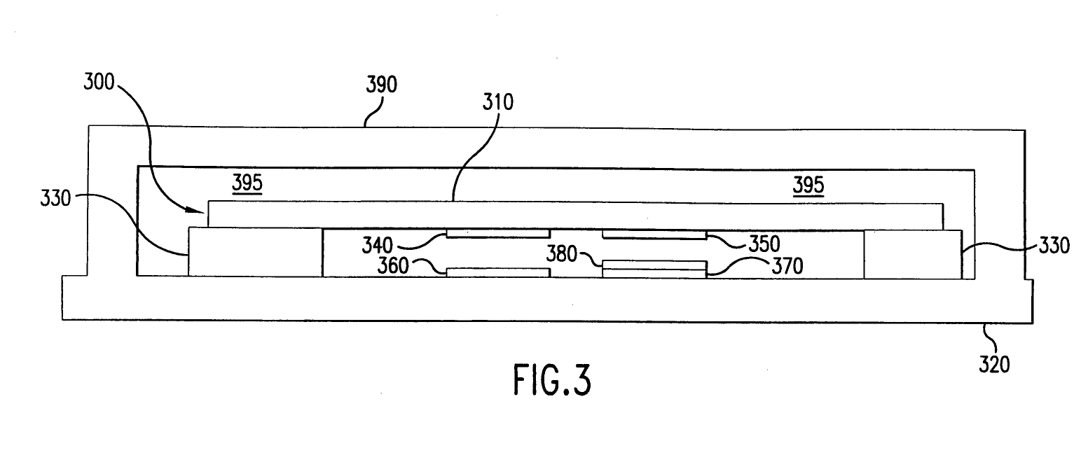

FIG. 3 shows an alternative embodiment of a varactor in accordance with the invention. The varactor 300 utilizes a deflecting beam 310 fixed at both ends. The varactor 300 shown, shown in FIG. 2, includes a substrate 320 which acts as support for the switching mechanism and provides a non-conductive dielectric platform. The deflecting beam 310 is fixed at each end to a beam support 330. The beam supports 330 are attached to the substrate 320. The deflecting beam 310 is constructed from a non-conductive material. The deflecting beam 310 has an attracted plate 340 and a first signal path plate 350 connected to one side between the supports 330. An actuator plate 360 is connected to the substrate directly opposing the attracted plate. A second signal path plate 370 is connected to the substrate directly opposing the signal path plate 350.

A dielectric pad 380 is commonly attached to one or both of the signal path plates 350,370. A dielectric pad is not shown on the signal path plate 350 in FIG. 3. The dielectric pad prohibits the signal path plates 350,370 from coming in contact during the bending of the deflecting beam. It is understood by those skilled in the art that electrostatically actuated micromachined high-power switches pass the signals capacitively because conduction by metal-to-metal can cause the contacts 350,370 to micro-weld. Further, the high heat present in a high power capacitive MEMS switch can cause annealing of the deflecting beam 310 also resulting in a short circuited MEMS switch.

The varactor 300 of FIG. 3 is surrounded by a packaging 390 which is connected to the substrate 320. The packaging 390 surrounding the varactor 300 forms a chamber 395 which is airtight. During construction of the varactor 300 and the packaging 390, all gas molecules are removed from the chamber 395. The chamber 395 is sealed to preserve the vacuum. Removal of the gas molecules results in elimination of collisions of gas molecules.

While only specific embodiments of the present invention have been described above, it will occur to a person skilled in the art that various modifications can be made within the scope of the appended claims.

1. A micromachined varactor comprising a deflecting beam, a pair of signal path plates attached to the deflecting beam and a means of deflecting said beam, wherein said varactor is packaged in an airtight vacuum.

2. The varactor of claim 1, wherein said deflecting beam is attached to a dielectric substrate and wherein said means of deflecting said beam comprises a first and a second actuator plate, said first actuator plate being attached to said beam and said second actuator plate being attached to said substrate.

3. The varactor of claim 2, wherein said deflecting beam is a cantilever beam.

4. The varactor of claim 1, wherein said deflecting beam is a beam with a first and a second end and said first and said second end are fixed and wherein said means of deflecting said beam comprises a first and a second actuator plate, said first actuator plate being attached to said beam and said second actuator plate being attached to said substrate.

5. A method of eliminating Brownian noise in a micromachined varactor, comprising the steps of:
packaging said varactor in an airtight chamber,
removing all gas molecules from said chamber, and
sealing said chamber to form a vacuum.

6. The method of claim 5 wherein packaging said varactor in an airtight chamber comprises the steps attaching said varactor to a dielectric substrate, placing a dielectric material around said varactor and attaching said material to said substrate.

7. The method of claim 5, wherein said varactor comprises a deflectable beam and a pair of signal path plates connected to said beam.

8. The method of claim 7, wherein said deflectable beam is a cantilever beam.

9. The method of claim 7, wherein said deflectable beam is a beam fixed at both ends.
